(19) United States
(12) Patent Application Publication
(10) Pub. No.: US 2024/0240318 A1
(43) Pub. Date: Jul. 18, 2024

(54) FILM-FORMING MATERIAL, FILM-FORMING COMPOSITION, FILM-FORMING METHOD USING FILM-FORMING MATERIAL AND FILM-FORMING COMPOSITION, AND SEMICONDUCTOR DEVICE FABRICATED USING FILM-FORMING METHOD

(71) Applicant: SOULBRAIN CO., LTD., Gyeonggi-do (KR)

(72) Inventors: Jong Moon KIM, Gyeonggi-do (KR); Jae Sun JUNG, Gyeonggi-do (KR); Kok Chew TAN, Gyeonggi-do (KR); Chang Bong YEON, Gyeonggi-do (KR)

(21) Appl. No.: 18/288,228

(22) PCT Filed: May 27, 2022
(86) PCT No.: PCT/KR2022/007539

§ 371 Date: Oct. 25, 2023

(30) Foreign Application Priority Data
May 31, 2021 (KR) 10-2021-0069947
May 25, 2022 (KR) 10-2022-0063835

(51) Int. Cl. C23C 16/455; C01G 25/02; C01G 27/02; C23C 16/40; H01L 21/02

(52) U.S. Cl. CPC C23C 16/45553; C01G 25/02; C01G 27/02; C23C 16/405; C23C 16/45527; H01L 21/02181; H01L 21/02189; C01P 2002/72; C01P 2006/40

(57) ABSTRACT

The present invention relates to a film-forming material, a film-forming composition, a film-forming method using the film-forming material and the film-forming composition, and a semiconductor device fabricated using the method. According to the present invention, by reducing a growth rate, even when forming a thin film on a substrate having a complex structure, a conformal thin film may be provided. In addition, by reducing impurities in the thin film and greatly improving the density of the thin film, leakage current generated due to oxidation of a lower electrode in the conventional high-temperature process may be greatly reduced. Therefore, the present invention has an effect of providing a film-forming material, a film-forming composition, a film-forming method using the film-forming material and the film-forming composition, and a semiconductor device fabricated using the film-forming method.

### TECHNICAL FIELD

The present invention relates to a film-forming material, a film-forming composition, a film-forming method using the film-forming material and the film-forming composition, and a semiconductor device fabricated using the film-forming method. More particularly, by controlling the rate of thin film formation through the film-forming material included in the film-forming composition and inducing ligand exchange with components that are not desired to remain on a substrate, a high-purity, conformal, and dense thin film is formed using a bottom-up method. In addition, crystallinity is improved by improving the quality of a film formed through a chemical reaction with a substrate. In addition, by reducing the concentration of impurities in a thin film, occurrence of leakage current is reduced.

### BACKGROUND ART

Recently, in the field of semiconductor technology, to improve technology through miniaturization of semiconductor devices, research on appropriate materials and process technologies is actively underway. In particular, among semiconductor processes, a process of forming oxide thin films such as TiO₂, ZrO₂, HfO₂, and Al₂O₃, which are high dielectric (high-k) materials used in capacitors for dynamic random access memory (DRAM), is being widely studied.

When fabricating a semiconductor, metal organic chemical vapor deposition (MOCVD) and atomic layer deposition (ALD) mainly used as metal oxide thin film forming processes. There are several limitations in forming metal oxide thin films through chemical vapor deposition and atomic layer deposition. For example, leakage current occurs due to miniaturization of semiconductor devices and oxidation of a lower electrode due to high-temperature processes. In addition, since the crystallinity of a thin film is low at a limited temperature, capacitance is limited.

Capacitors for DRAM require high capacitance and leakage current of 10⁻⁷ A/cm² or less. In particular, leakage current is a key variable in meeting the stringent requirements of DRAM cells and providing a dielectric thin film (W. Jeon, Journal of Materials Research 35 (7), 1 (2019) and J. Lee, D. Park, S. Yew, S. Shin, J. Noh, H. Kim, B. Choi, IEEE Electron Device Letters 38 (11) (2017)).

Niinisto et al. reported that, when an amorphous thin film having a thickness of 8.6 nm and a monoclinic thin film were post-annealed at 500° C. through ALD of HfO₂ at 250 to 400° C. using CpHf (NMe₂)₃ and ozone, a leakage current intensity of 1×10⁻⁷ A/cm² at 1 V was observed (J. Niinisto, M. Mantymaki, K. Kukli, L. Costelle, E. Puukilainen, M. Ritala, M. Leskela, Journal of Crystal Growth, 312, 245 (2010)).

However, instead of interface-related leakage current conduction, such as Zro₂ and HfO₂, bulk-related leakage conduction mechanisms such as trap-assisted tunneling (TAT) or Poole-Frenkel (P-F) emission are known to be dominant (W. Y. Choi, G. Yoon, W. Y. Chung, Y. Cho, S. SHin and K. H. Ahn, Micromachines 10, 256 (2019)). In particular, the carrier conduction mechanism is known to largely depend on the bulk characteristics of dielectric film defects, such as grain boundaries, internal impurities (oxygen deficiency, etc.), and external impurities incorporated into a thin film during a deposition process.

Therefore, rather than using other high dielectric materials or metal electrodes with different work functions, technology to reduce the causes of defects in bulk Zro₂ and HfO₂ is effective.

A thin film according to the present invention may induce ligand exchange with components that are not desired to remain on a substrate through a film-forming material that provides both a blocking agent and a ligand exchange reaction agent, may reduce leakage current while improving film quality and film conformality, and may ensure the reliability of semiconductor devices even at low temperatures such as 250° C.

### Disclosure

### Technical Problem

Therefore, the present invention has been made in view of the above problems, and it is one object of the present invention to provide a conformal thin film by reducing a growth rate even when forming a thin film on a substrate having a complex structure, reduce impurities in the thin film, improve the density of the thin film, and reduce leakage current.

It is another object of the present invention to secure the reliability of semiconductor devices by providing a thin film having a high dielectric (high-k) constant at low temperatures.

### Technical Solution

In accordance with one aspect of the present invention, provided is a film-forming material including a blocking agent and a ligand exchange reaction agent.

The blocking agent may be an unsaturated hydrocarbon having 2 to 15 carbon atoms formed from the film-forming material in a film formation process.

The ligand exchange reaction agent may be a hydrogen halide or halogen gas that is formed from the film-forming material in the film formation process and undergoes an exchange reaction with a ligand of an inorganic precursor.

The film-forming material may be a branched, cyclic, or aromatic compound represented by Chemical Formula 1 below.

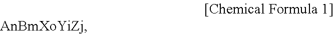

wherein A is carbon or silicon; B is hydrogen or an alkyl having 1 to 3 carbon atoms; X includes one or more of fluorine (F), chlorine (Cl), bromine (Br), and iodine (I); Y and Z independently include one or more selected from the group consisting of oxygen, nitrogen, sulfur, and fluorine, and are different from each other; n is an integer from 1 to 15; o is an integer greater than or equal to 1; m is 0 to 2n+1; and i and j are integers from 0 to 3.

In accordance with another aspect of the present invention, provided is a bottom-up thin film composition including a pulse precursor.

The pulse precursor may be a hybrid precursor including the above-described film-forming material (hereinafter also referred to as organic precursor) and an inorganic precursor.

The inorganic precursor may include one or more selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, Tl, Pb, Bi, Pt, At, and Tn.

The inorganic precursor is a thin film residual precursor including one or more selected from the group consisting of a compound represented by Chemical Formula 2a below, a compound represented by Chemical Formula 2b below, and a compound represented by Chemical Formula 2c below.

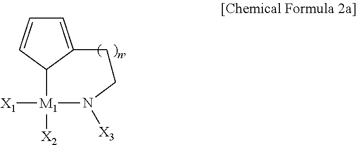

wherein M₁ is Zr, Hf, Si, Ge, or Ti; X₁, X₂, and X₃ are independently —NRIR₂ or —OR₃; R₁ to R₃ are independently an alkyl group having 1 to 6 carbon atoms; and n is 1 or 2.

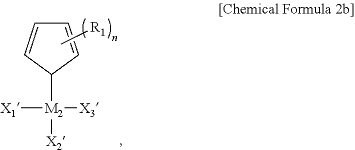

wherein M is Zr, Hf, Si, Ge, or Ti; R₁ is hydrogen or an alkyl group having 1 to 4 carbon atoms; n is an integer from 0 to 5; X′₁, X′₂, and X′ₛ are independently —NRIR₂ or —OR₃; and R′₁ to R′ₛ are independently an alkyl group having 1 to 6 carbon atoms.

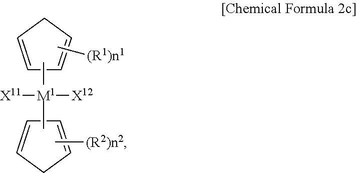

wherein M¹ is Zr, Hf, Si, Ge, or Ti; X¹¹ and X¹² are each independently selected from the group consisting of an alkyl group, —NR₃R₄, and —OR₃; R¹ to R² are each independently an alkyl group having 1 to 6 carbon atoms; and n¹ and n² are each independently an integer from 0 to 5.

A weight ratio of the inorganic precursor to the film-forming material may be 1:99 to 99:1.

The composition may include a reaction gas pulse.

The reaction gas pulse may be an oxidizing agent pulse, a nitriding agent pulse, or a reducing agent pulse.

The film-forming composition may be a composition for bottom-up thin films or selective area thin films.

In accordance with still another aspect of the present invention, provided is a film-forming method including:
injecting the film-forming material of claim 1 into a chamber and depositing the film-forming material on a substrate loaded into the chamber;
injecting an inorganic precursor and depositing the inorganic precursor on the substrate; and
injecting a reaction gas pulse and depositing the reaction gas pulse on the substrate,
wherein the inorganic precursor includes one or more selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, Tl, Pb, Bi, Pt, At, and Tn.

In accordance with still another aspect of the present invention, provided is a film-forming method including:
injecting an inorganic precursor into a chamber and depositing the inorganic precursor on a substrate loaded into the chamber;
injecting the above-described film-forming material and depositing the film-forming material on the substrate; and
injecting a reaction gas pulse and depositing the reaction gas pulse on the substrate,
wherein the inorganic precursor includes one or more selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, Tl, Pb, Bi, Pt, At, and Tn.

In accordance with still another aspect of the present invention, provided is a film-forming method including:
injecting the above-described film-forming material and an inorganic precursor into a chamber and depositing the film-forming material and the inorganic precursor on a substrate loaded into the chamber; and
injecting a reaction gas pulse and depositing the reaction gas pulse on the substrate,
wherein the inorganic precursor includes one or more selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, Tl, Pb, Bi, Pt, At, and Tn.

The film-forming method may include depositing a blocking agent and a ligand exchange reaction agent formed from the film-forming material on the substrate; and exchanging a ligand of the inorganic precursor by the ligand exchange reaction agent.

The inorganic precursor may remain on the substrate, and the film-forming material may not remain on the substrate.

The substrate may have an aspect ratio of 10:1 or more.

The film-forming material and the inorganic precursor may be provided in a pulse phase.

The film-forming method may be performed at 200 to 800° C.

As the reaction gas pulse, a pulse of an oxidizing agent, a reducing agent, or a nitriding agent may be used.

The film-forming method may be performed by atomic layer deposition, chemical vapor deposition, plasma atomic layer deposition, or plasma chemical vapor deposition.

The film-forming method may be a bottom-up thin film.

In the film-forming method, a thin film, in which a metal oxide thin film, a metal nitride thin film, a metal thin film, or two or more thin films thereof have a selective region, may be formed.

In accordance with still another aspect of the present invention, provided is a method of forming a bottom-up thin film, the method including injecting a bottom-up thin film composition including the above-described film-forming material and a pulse precursor including the precursor into a chamber and bottom-up depositing the inorganic precursor on a substrate loaded into the chamber.

The bottom-up depositing may include injecting the film-forming material pulse onto the substrate and performing purging; injecting the film-forming material pulse onto the substrate and performing purging; and injecting a reaction gas pulse onto the substrate and performing purging.

The bottom-up depositing may include injecting the inorganic precursor pulse onto the substrate and performing purging; injecting the film-forming material pulse onto the substrate and performing purging; and injecting a reaction gas pulse onto the substrate and performing purging.

The bottom-up depositing may include injecting the film-forming material pulse onto the substrate and performing purging; injecting the film-forming material pulse onto the substrate and performing purging; injecting a reaction gas pulse onto the substrate and performing purging; and injecting the film-forming material pulse onto the substrate and performing purging.

The bottom-up depositing may include simultaneously injecting the inorganic precursor and the organic precursor onto the substrate and performing purging; and injecting a reaction gas pulse onto the substrate and performing purging.

The substrate may have an aspect ratio of 10:1 or more.

The film-forming material and the inorganic precursor may be provided in a pulse phase.

The film-forming method may be performed at 200 to 800° C.

As the reaction gas pulse, a pulse of an oxidizing agent, a reducing agent, or a nitriding agent may be used.

The inorganic precursor may remain on the substrate, and the film-forming material may not remain on the substrate.

The method of forming a bottom-up thin film may be performed by atomic layer deposition, chemical vapor deposition, plasma atomic layer deposition, or plasma chemical vapor deposition.

In the method of forming a bottom-up thin film, a thin film, in which a metal oxide thin film, a metal nitride thin film, a metal thin film, a non-metal oxide thin film, a non-metal nitride thin film, a dielectric thin film, or two or more thin films thereof have a selective region, may be formed. In this case, non-metal refers to materials other than metals known in the art, and for example, includes silicon and the like.

In accordance with still another aspect of the present invention, provided is a semiconductor substrate fabricated using the above-described film-forming method.

The semiconductor substrate may be low-resistive metal gate interconnects, a high-aspect-ratio 3D metal-insulator-metal (MIM) capacitor, a DRAM trench capacitor, 3D gate-all-around (GAA), or 3D NAND.

In accordance with yet another aspect of the present invention, provided is a semiconductor device including the above-described semiconductor substrate.

### Advantageous Effects

According to the present invention, the present invention has an effect of providing a film-forming material capable of both a blocking agent and a ligand exchange reaction agent during film formation.

According to the present invention, the present invention has an effect t of providing a film-forming composition capable of inducing ligand exchange with components that are not desired to remain on a substrate through the film-forming material and providing a conformal thin film even when forming a thin film on a substrate having a complex structure.

According to the present invention, the present invention has an effect of providing a film-forming composition capable of more effectively removing process by-products and unwanted components generated during film formation and improving the quality of a thin film by improving the crystallinity of the thin film by reducing a deposition rate and appropriately reducing a film formation rate.

According to the present invention, the present invention has an effect of providing a bottom-up thin film composition capable of providing a conformal thin film using a bottom-up method even when forming a thin film on a substrate having a complex structure.

According to the present invention, the present invention has an effect of providing a thin film composition capable of more effectively removing process by-products during bottom-up thin film formation and improving the quality of a thin film by improving the crystallinity of the thin film by reducing a deposition rate and appropriately reducing a thin film growth rate.

According to the present invention, the present invention has an effect of providing a film-forming composition capable of reducing leakage current caused by oxidation of a lower electrode in the conventional high-temperature process by reducing impurities within a thin film and greatly improving the density of the thin film; a film-forming method using the film-forming composition; and a semiconductor device fabricated using the method.

### DESCRIPTION OF DRAWINGS

FIG. 1 includes diagrams schematically showing a film formation cycle using a film-forming composition according to the present invention. The left diagram shows a film formation cycle (hereinafter also referred to as the first process) in which an inorganic precursor is added after a film-forming material is added, and the right diagram shows a film formation cycle (hereinafter also referred to as the second process) in which a film-forming material is added after an inorganic precursor of a film-forming composition is added.

FIG. 2 is a GPC analysis graph showing the deposition rates of the bottom-up thin films of Examples 1 to 3 and Examples 6 to 8 and the deposition rates of the bottom-up thin films of Comparative Examples 1 to 6 (Ref. HfO₂).

FIG. 3 includes TEM images of a cross section at a point 200 nm below the top of an HfO₂ thin film deposited on a substrate having a trench structure having an aspect ratio (length/diameter) of 22.6:1 at 320° C. according to Example 1 of the present invention or Comparative Example 1 and TEM images of a cross section at a point 100 nm above the bottom of the HfO₂ thin film.

FIG. 4 is a flowchart for schematically explaining a first process in which a blocking agent generated when a film is formed using a film-forming material according to Example 1 of the present invention and a ligand exchange reaction agent are deposited on a substrate, and then an inorganic precursor is adsorbed.

FIG. 5 is a flowchart for schematically explaining a process in which, in a product of the first process in which, in FIG. 4, the blocking agent and the ligand exchange reaction agent are deposited on a substrate, and then the inorganic precursor is adsorbed, dialkylamine and Cp as the ligands of the inorganic precursor are each subjected to ligand exchange by the ligand exchange reaction agent, and a metal oxide film is formed by a reaction gas.

FIG. 6 includes SIMS analysis graphs showing the reduction rates of carbon (C) and iodine (I) elements depending on the depth of a bottom-up thin film formed at a deposition temperature of 320° C. (FIG. 6(a), Example 1 and Comparative Example 1), 300° C. (FIG. 6(b), Example 2 and Comparative Example 2), or 250° C. (FIG. 6(c), Example 3 and Comparative Example 3).

FIG. 7 is a film density analysis graph of bottom-up thin films formed at a deposition temperature of 320° C., 300° C., or 250° C. in Examples 1 to 3 of the present invention and Comparative Examples 1 to 3.

FIG. 8 includes XPS analysis graphs showing component contents (atomic %) depending on the depths of bottom-up thin films formed at 250° C. in Example 3 of the present invention and Comparative Example 3.

FIG. 9 is an XRD pattern analysis graph of bottom-up thin films formed at a deposition temperature of 250° C. in Example 3 of the present invention and Comparative Examples 1 and 3.

### BEST MODE

Hereinafter, a film-forming composition, a bottom-up thin film composition, a film-forming method using the film-forming composition and the bottom-up thin film composition, a semiconductor substrate fabricated using the method, and a semiconductor device fabricated using the method according to the present invention will be described in detail.

The term “blocking agent” used in the present invention, unless otherwise specified, refers to an additive that controls a film formation rate by being adsorbed onto a substrate in competition with an inorganic precursor or inhibits dense adsorption of the inorganic precursor. A specific example is shown in FIG. 4(b). FIG. 4 below is a flowchart for schematically explaining a first process in which a blocking agent and a ligand exchange reaction agent generated from a film-forming material during film formation are deposited on a substrate, and then an inorganic precursor is adsorbed thereon. As shown in FIG. 4 below, the film-forming material injected onto the substrate in FIG. 4(a) is, as shown in FIG. 4(b), divided into the blocking agent and the ligand exchange reaction agent, and each is weakly adsorbed onto the substrate. Accordingly, the site at which an inorganic precursor provided in (c) will be adsorbed is reduced.

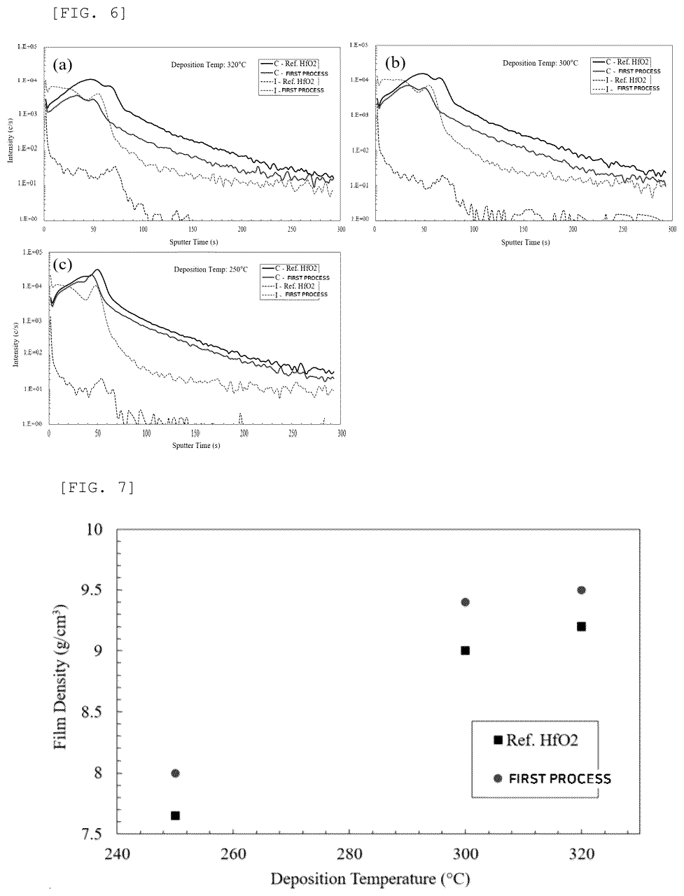

The term “ligand exchange reaction agent” used in the present invention, unless otherwise specified, refers to an additive that performs an exchange reaction with the ligand of the inorganic precursor. A specific example is shown in FIGS. 5(a) and 5 (b). FIG. 5 below is a flowchart for schematically explaining a process in which, in a product of the first process in which, in FIG. 4, the blocking agent and the ligand exchange reaction agent are deposited on a substrate, and then the inorganic precursor is adsorbed, dialkylamine and Cp as the ligands of the inorganic precursor are each subjected to ligand exchange by the ligand exchange reaction agent, and a metal oxide film is formed by a reaction gas.

As shown in FIG. 5 below, in a product (corresponding to FIG. 4(d) or FIG. 5(a)) of the first process in which the above-described blocking agent and ligand exchange reaction agent are deposited on the substrate and then the inorganic precursor adsorbed thereon, an exchange reaction (corresponding to FIG. 5(a)) with dialkylamine as the ligand of the inorganic precursor and an exchange reaction (corresponding to FIG. 5(b)) with Cp as another ligand of the inorganic precursor are performed so that a halogen remains at the corresponding site. Then, a metal oxide film is formed by reaction with the injected reaction gas.

The term “bottom up” used in the present invention, unless otherwise specified, refers to growth from the bottom of a substrate having a trench structure. For example, the substrate having a trench structure may have an aspect ratio of 10:1 or more or 20:1 or more.

The aspect ratio, unless otherwise specified, refers to the ratio of the length/diameter (L/D) of the trench structure. Here, the length and diameter each define parts commonly mentioned in the art.

The present inventors confirmed that, when a thin film was formed on a substrate loaded into a chamber using a film-forming composition including an inorganic precursor and a film-forming material, even at a low temperature of 250° C., the growth rates at the top and bottom of the thin film formed after deposition were greatly reduced. As a result, the conformal properties of a trench structure having a high aspect ratio were greatly improved. In addition, contrary to expectations, the residual amounts of carbon and iodine were reduced, and the density and impurities of the thin film were greatly improved. Based on these results, the present inventors conducted further studies to complete the present invention.

For example, the film-forming method may include a step of vaporizing an inorganic precursor and a film-forming material separately or simultaneously and adsorbing the inorganic precursor and the film-forming material on a substrate loaded into a chamber; a step of purging the inside of the chamber with a purge gas; a step of supplying a reaction gas into the chamber; and a step of purging the inside of the chamber with a purge gas. In this case, the film formation rate may be appropriately reduced. In addition, even when a deposition temperature decreases during film formation, the density, crystallinity, conformal properties, and dielectric properties of a thin film may be improved, and leakage current may be effectively reduced, thereby greatly improving film quality.

As a preferred example, the film-forming method may include a step of injecting a bottom-up thin film composition including a pulse precursor into a chamber and depositing the bottom-up thin film composition on a substrate loaded into the chamber, wherein the pulse precursor includes an inorganic precursor and an organic precursor; and a step of simultaneously injecting the inorganic precursor and the organic precursor and then injecting a reaction gas pulse to deposit the inorganic precursor and the organic precursor on the substrate. In this case, the film formation rate may be appropriately reduced. In addition, even when a deposition temperature decreases during thin film formation, the density, crystallinity, conformal properties, and dielectric properties of a bottom-up thin film may be improved, and leakage current may be effectively reduced, thereby greatly improving film quality.

As a preferred example, the film-forming method may include a step of injecting the film-forming material of claim 1 into a chamber and depositing the film-forming material on a substrate loaded into the chamber; a step of injecting an inorganic precursor and depositing the inorganic precursor on the substrate; and a step of injecting a reaction gas pulse and depositing the reaction gas pulse on the substrate. In this case, the film formation rate may be appropriately reduced. In addition, even when a deposition temperature decreases during film formation, the density, crystallinity, conformal properties, and dielectric properties of a thin film may be improved, and leakage current may be effectively reduced, thereby greatly improving film quality.

As another preferred example, the film-forming method may include a step of injecting an inorganic precursor into a chamber and depositing the inorganic precursor on a substrate loaded into the chamber; a step of injecting a film-forming material and depositing the film-forming material on the substrate; and a step of injecting a reaction gas pulse and depositing the reaction gas pulse on the substrate. In this case, the film formation rate may be appropriately reduced. In addition, even when a deposition temperature decreases during film formation, the density, crystallinity, conformal properties, and dielectric properties of a thin film may be improved, and leakage current may be effectively reduced, thereby greatly improving film quality.

As another preferred example, the film-forming method may include a step of injecting a film-forming material and an inorganic precursor into a chamber and depositing the film-forming material and the inorganic precursor on a substrate loaded into the chamber; and a step of injecting a reaction gas pulse and depositing the reaction gas pulse on the substrate. In this case, the film formation rate may be appropriately reduced. In addition, even when a deposition temperature decreases during film formation, the density, crystallinity, conformal properties, and dielectric properties of a thin film may be improved, and leakage current may be effectively reduced, thereby greatly improving film quality.

As another preferred example, the film-forming method may include a step of injecting a film-forming material onto a substrate and performing purging; a step of injecting an inorganic precursor onto the substrate and performing purging; a step of injecting a reaction gas pulse onto the substrate, performing purging, and depositing the inorganic precursor on the substrate; and a step of injecting the film-forming material onto the substrate and performing purging. In this case, the film formation rate may be appropriately reduced. In addition, even when a deposition temperature decreases during film formation, the density, crystallinity, conformal properties, and dielectric properties of a thin film may be improved, and leakage current may be effectively reduced, thereby greatly improving film quality.

The thin film manufactured by the film-forming method may be a bottom-up thin film. Within the thin film, the inorganic precursor remains and is deposited to form the thin film, but the film-forming material does not remain.

The inorganic precursor, the film-forming material, the reaction gas, and the gas used for purging may be independently transferred into the chamber, preferably by a VFC method, a DLI method, or an LDS method, more preferably an LDS method.

The chamber may be a CVD chamber or an ALD chamber, but the present invention is not limited thereto.

In one embodiment of the present invention, the film-forming material may include a blocking agent and a ligand exchange reaction agent.

As shown in FIG. 4(b), the blocking agent may be an unsaturated hydrocarbon having 2 to 15 carbon atoms formed from a film-forming material in the film formation process. Preferably, the blocking agent may be an unsaturated hydrocarbon having 2 to 15 carbon atoms having a tertiary structure. In this case, the effect of blocking the inorganic precursor from accessing the substrate to be adsorbed may be maximized.

As shown in FIGS. 5(a) and 5 (b), the ligand exchange reaction agent may be a hydrogen halide or halogen gas that is formed from the film-forming material during the film formation process and undergoes an exchange reaction with the ligand of the inorganic precursor. When the ligand exchange reaction agent is a hydrogen halide, the effect of blocking the inorganic precursor from accessing the substrate to be adsorbed and the effect of performing an exchange reaction with the ligand of the adjacent adsorbed inorganic precursor may be maximized. Accordingly, the ligand exchange reaction agent is preferably a hydrogen halide.

At this time, F, Cl, Br, or I may be used as the halogen. Considering reactivity with a reaction gas, it may be desirable to use I or Br as the halogen.

The film-forming material used in the present invention refers to a material that is substantially non-reactive with an inorganic precursor described later and does not remain in a thin film. For example, the film-forming material may be a branched, cyclic, or aromatic compound represented by Chemical Formula 1 below.

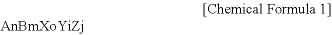

In Chemical Formula 1, A is carbon or silicon; B is hydrogen or an alkyl having 1 to 3 carbon atoms; X includes one or more of fluorine (F), chlorine (Cl), bromine (Br), and iodine (I); Y and Z independently include one or more selected from the group consisting of oxygen, nitrogen, sulfur, and fluorine, and are different from each other; n is an integer from 1 to 15; o is an integer greater than or equal to 1; m is 0 to 2n+1; and i and j are integers from 0 to 3. In this case, the compound may act as a precursor that does not remain in a thin film and may provide a high dielectric constant by effectively expressing the desired effect of the present invention.

Unless otherwise specified, the term “non-residual” used in the present invention refers to the case in which C element is present in an amount of less than 0.1 atom % and N element is present in an amount of less than 0.1 atom %.

The film-forming material may be preferably a compound having a purity of 99.9% or more, 99.95% or more, or 99.99% or more. For reference, when a compound having a purity of less than 99% is used, impurities may be generated. Thus, it is desirable to use a compound having a purity of 99% or more.

For example, when a blocking agent and a ligand exchange reaction agent are formed from the film-forming material, when the film-forming material is tert-butyl iodide, the blocking agent may be 2-methylpropene, and the ligand exchange reaction agent may be hydrogen iodide.

The film-forming material may be supplied in a pulse phase using a vapor flow controller (VFC) and/or a liquid delivery system (LDS). At this time, the pulse phase may be any pulse phase used in the art.

In one embodiment of the present invention, the film-forming composition may include the film-forming material and an inorganic precursor.

In one embodiment of the present invention, the film-forming composition may be a bottom-up thin film composition.

In one embodiment of the present invention, the bottom-up thin film composition may include a pulse precursor.

In the present invention, the pulse precursor refers to a precursor that may be supplied in a pulse phase using a vapor flow controller (VFC) and/or a liquid delivery system (LDS). At this time, the pulse phase may be any pulse phase used in the art.

For example, the pulse precursor may be a hybrid precursor including an inorganic precursor and an organic precursor.

The inorganic precursor used in the present invention may include substances that remain in a thin film and improve conductivity. For example, the inorganic precursor may be a substance represented by Chemical Formula 2 below.

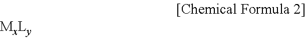

In Chemical Formula 2, x is an integer from 1 to 3; M is selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, Tl, Pb, Bi, Pt, At, and Tn; y is an integer from 1 to 6; L is H, C, N, O, F, P, S, Cl, Br, or I or a ligand consisting of a combination of two or more selected from the group consisting of H, C, N, O, F, P, S, Cl, and Br. In this case, the desired effect of the present invention may be effectively achieved, and a high dielectric constant may be obtained.

For example, considering thermal stability and reactivity, the inorganic precursor is preferably a thin film residual precursor including one or more selected from the group consisting of a compound represented by Chemical Formula 2a below, a compound represented by Chemical Formula 2b below, and a compound represented by Chemical Formula 2c below.

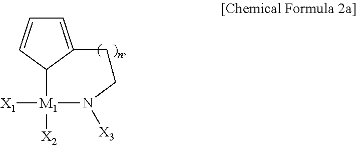

wherein M₁ is Zr, Hf, Si, Ge, or Ti; X₁, X₂, and X₃ are independently —NR₁R₂ or —OR₃; R₁ to R₃ are independently an alkyl group having 1 to 6 carbon atoms; and n is 1 or 2.

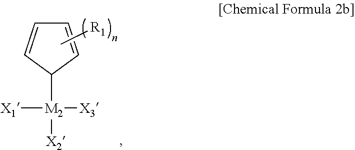

wherein M is Zr, Hf, Si, Ge, or Ti; R₁ is hydrogen or an alkyl group having 1 to 4 carbon atoms; n is an integer from 0 to 5; X′₁, X′₂, and X′₃ are independently —NR₁R₂ or —OR₃; and R′₁ to R′₃ are independently an alkyl group having 1 to 6 carbon atoms.

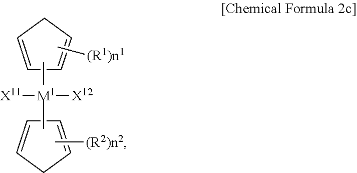

wherein M¹ is Zr, Hf, Si, Ge, or Ti; X¹¹ and X¹² are each independently selected from the group consisting of an alkyl group, —NR₃R₄, and —OR₃; R¹ to R² are each independently an alkyl group having 1 to 6 carbon atoms; and n¹ and n² are each independently an integer from 0 to 5.

A weight ratio of the inorganic precursor to the film-forming material may be 1:99 to 99:1, 1:90 to 90:1, 1:85 to 85:1, or 1:80 to 80:1.

The composition may include a pulse of a reaction gas, and the reaction gas may include one or more selected from an oxidizing agent, a nitriding agent, and a reducing.

As the oxidizing agent, the nitriding agent, and the reducing agent, substances commonly used in the art may be used. For example, the oxidizing agent may be 03, 02, or a mixture thereof, the nitriding agent may be NH₃, N₂H₂, N₂, or a mixture thereof, and the reducing agent may be H₂, but the present invention is not limited thereto.

The film-forming method of the present invention includes a step of depositing an inorganic precursor on a substrate using a film-forming material.

In the film-forming method of the present invention, for example, the step of depositing the inorganic precursor on the substrate may include a step of depositing a blocking agent and a ligand exchange reaction agent formed from the film-forming material on a substrate; and a step of exchanging the ligand of the inorganic precursor by the ligand exchange reaction agent and depositing the inorganic precursor on the substrate.

In the film-forming method of the present invention, as a preferred example, the step of depositing the inorganic precursor on the substrate may include a step of depositing a blocking agent and a ligand exchange reaction agent formed from the film-forming material on a substrate; a step of exchanging the ligand of the inorganic precursor by the ligand exchange reaction agent; and a step of injecting a pulse of a reaction gas onto the substrate and depositing the inorganic precursor on the substrate.

At this time, the inorganic precursor may be added after injection of the film-forming material, before injection of the film-forming material, or simultaneously with injection of the film-forming material.

In the method of forming a bottom-up film of the present invention, as a preferred example, the step of bottom-up depositing the inorganic precursor on the substrate may include a step of injecting the film-forming material pulse onto the substrate and performing purging; a step of injecting the inorganic precursor pulse onto the substrate and performing purging; and a step of injecting a reaction gas pulse onto the substrate and performing purging.

When the inorganic precursor is added after injection of the film-forming material, as shown in FIGS. 4 and 5 below, a blocking reaction and a ligand exchange reaction may be performed.

In the method of forming a bottom-up film of the present invention, as another preferred example, the step of bottom-up depositing the inorganic precursor on the substrate may include a step of injecting the inorganic precursor pulse onto the substrate and performing purging; a step of injecting the film-forming material pulse onto the substrate and performing purging; and a step of injecting a reaction gas pulse onto the substrate and performing purging.

In addition, in the method of forming a bottom-up film of the present invention, as another preferred example, the step of bottom-up depositing the inorganic precursor on the substrate may include a step of injecting the film-forming material pulse onto the substrate and performing purging; a step of injecting the inorganic precursor pulse onto the substrate and performing purging; a step of injecting a reaction gas pulse onto the substrate and performing purging; and a step of injecting the film-forming material pulse onto the substrate and performing purging.

In addition, in the method of forming a bottom-up film of the present invention, as another preferred example, the step of bottom-up depositing the inorganic precursor on the substrate may include a step of simultaneously injecting the inorganic precursor pulse and the film-forming material pulse onto the substrate and performing purging; and a step of injecting a reaction gas pulse onto the substrate and performing purging.

The substrate may be a substrate having a trench structure having an aspect ratio of 10:1 or more or 20:1 or more.

For example, in the film-forming method, the deposition temperature may be 200 to 800° C., as a specific example, 200 to 600° C., preferably 250 to 450° C., as a specific example, 250 to 420° C., 250 to 320° C., 380 to 420° C., or 400 to 450° C. Within this range, thin film quality and step coverage may be greatly improved.

For example, in the film-forming method, as the reaction gas, a reducing agent, a nitriding agent, or an oxidizing agent may be used. When necessary, different reaction gases may be applied to some selected areas and the remaining areas.

For example, the film-forming method may be performed by atomic layer deposition or chemical vapor deposition. When necessary, the film-forming method may be performed by plasma atomic layer deposition or plasma chemical vapor deposition.

For example, in the film-forming method, a thin film, in which a metal oxide thin film, a metal nitride thin film, a metal thin film, a non-metal oxide thin film, a non-metal nitride thin film, a dielectric thin film, or two or more thin films thereof have a selective region, may be formed.

According to one embodiment of the present invention, the present invention may provide a thin film manufactured by the above-described film-forming method.

The thin film may be used as a diffusion barrier, an etching stop film, a charge trap, a selective region deposition film, a bottom-up thin film, and the like.

According to one embodiment of the present invention, the present invention may provide a semiconductor substrate fabricated by the above-described film-forming method.

The semiconductor substrate may be low-resistive metal gate interconnects, a high-aspect-ratio 3D metal-insulator-metal (MIM) capacitor, a DRAM trench capacitor, 3D gate-all-around (GAA), or 3D NAND.

In addition, according to another embodiment of the present invention, the present invention may provide a semiconductor device including the above-described semiconductor substrate.

For example, a capacitor including the thin film according to the present invention may be provided by laminating 2 to 3 or more layers. At this time, the type of inorganic precursor constituting each layer may be different. When necessary, the same type of inorganic precursor may be used.

For example, a capacitor may be formed by sequentially forming a lower electrode, a dielectric film, and a second electrode on the semiconductor substrate.

At this time, the lower electrode may be a storage electrode of a DRAM device or other device, or an electrode of a decoupling capacitor.

For example, the lower electrode may be manufactured in a cylinder shape or pillar shape that may secure a large surface area, and may be formed of a conductive layer or a metal layer.

The dielectric film may be a metal oxide film. When deposited using the film-forming composition according to the present invention, even when the dielectric film is formed on the lower electrode with a lower step or topology, uniform thickness and appropriate adhesion may be achieved.

An upper electrode formed on the dielectric film may be composed of the same conductive layer or metal layer as the lower electrode.

Hereinafter, the present invention will be described in more detail with reference to the following preferred examples. However, these examples are provided for illustrative purposes only and should not be construed as limiting the scope and spirit of the present invention. In addition, it will be apparent to those skilled in the art that various changes and modifications may be made without departing from the spirit and scope of the present invention, and such changes and modifications are also within the scope of the appended claims.

### EXAMPLES

### Example 1

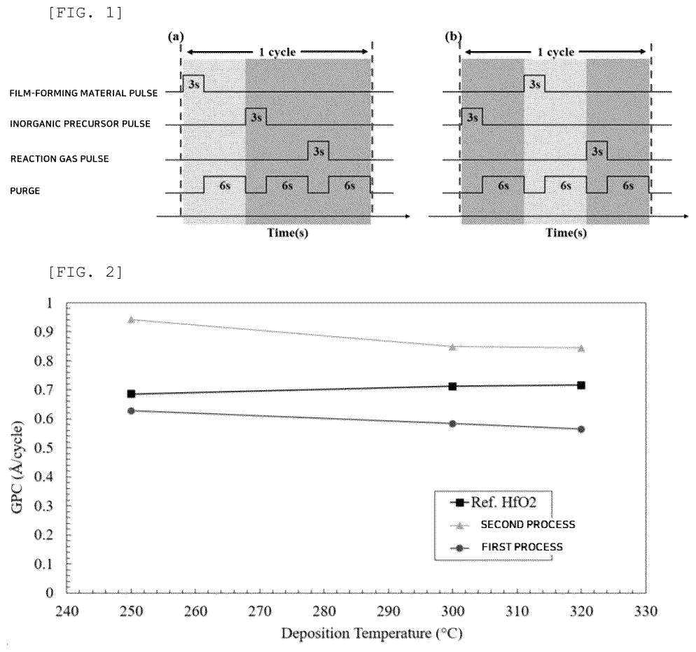

According to the thin film formation cycle shown in the left diagram of FIG. 1 below, an HfO₂ bottom-up thin film was laminated on an Sio₂ substrate having a trench structure having an aspect ratio of 22.6:1 (length:diameter).

The left diagram of FIG. 1 corresponds to the experiment of injecting an inorganic precursor pulse after injection of a film-forming material pulse among the bottom-up thin film composition according to the present invention, and is referred to as the first process.

Specifically, a cycle of injecting the film-forming material pulse for 3 seconds and then performing purging for 6 seconds; injecting the inorganic precursor pulse for 3 seconds and then performing purging for 6 seconds; and injecting a reaction gas pulse for 3 seconds and then performing purging for 6 seconds is included.

The above-described HfO₂ bottom-up thin film was formed by performing a deposition process in a 12-inch ALD system equipped with a shower head.

CpHf, which is a compound represented by Chemical Formula 3-1 below, was used as the inorganic precursor. CpHf was purchased from Sigma Co. and used without purification.

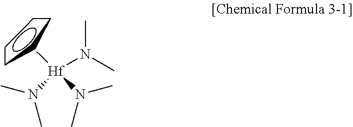

TBI, which is a compound represented by Chemical Formula 3-2 below, was used as the film-forming material. TBI was synthesized by the applicant and purified to 99.9% purity before use.

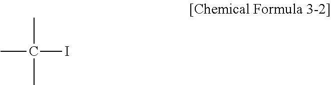

The prepared film-forming material was placed in a canister and supplied to a vaporizer heated to 90° C. at a flow rate of 0.01 g/min using a liquid mass flow controller (LMFC) at room temperature. The prepared CpHf was placed in a separate canister and supplied to a separate vaporizer heated to 170° C. at a flow rate of 0.1 g/min.

The film-forming material vaporized in the vaporizer was injected into a deposition chamber into which a substrate on which TiN had been grown to a thickness of 20 nm on 100 nm-thick SiO₂ grown on a Si wafer for 3 seconds was loaded, and then argon gas was supplied at 300 sccm for 6 seconds to perform argon purging. The substrate on which the metal oxide film was to be formed was heated to 320° C., and pressure in the reaction chamber was controlled at 0.74 Torr.

Next, CpHf vaporized in the vaporizer was injected into the deposition chamber for 3 seconds, and then argon gas was supplied at 300 sccm for 6 seconds to perform argon purging. The substrate on which the metal oxide film was to be formed was heated to 320° C., and pressure in the reaction chamber was controlled at 0.74 Torr.

Next, ozone as a reactive gas was introduced into the reaction chamber at 1,000 sccm for 3 seconds, and then argon purging was performed for 6 seconds. The substrate on which the metal oxide film was to be formed was heated to 320° C., and pressure in the reaction chamber was controlled at 0.74 Torr.

This process was repeated 100 times to form an HfO₂ thin film, which is a self-limiting atomic layer.

### Example 2

An HfO₂ thin film was formed in the same manner as in Example 6, except that the temperature for heating the substrate in Example 1 was adjusted to 300° C.

### Example 3

An HfO₂ thin film was formed in the same manner as in Example 6, except that the temperature for heating the substrate in Example 1 was adjusted to 250° C.

### Example 4

An HfO₂ thin film as a self-limiting atomic layer was formed in the same manner as in Example 1, except that tetrakis(ethylmethylamino) hafnium (TEMAH), which is a compound represented by Chemical Formula 3-3 below, was used instead of the inorganic precursor of Example 1.

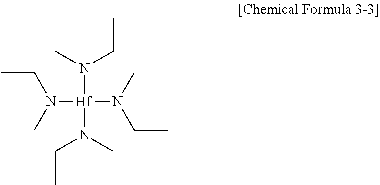

### Example 5

An HfO₂ thin film as a self-limiting atomic layer was formed in the same manner as in Example 1, except that TBB, which is a compound represented by Chemical Formula 3-4 below, was used instead of the film-forming material of Example 1. TBB was synthesized by the applicant and then purified to 99.9% purity.

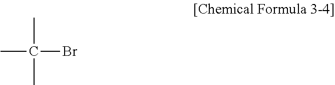

### Example 6

The same process as in Example 1 was repeated except that the thin film formation cycle shown in the right diagram of FIG. 1 was used instead of the thin film formation cycle shown in the left diagram of FIG. 1 used in Example 1.

Specifically, using the film formation cycle shown in the right diagram of FIG. 1, an HfO₂ bottom-up thin film was laminated on an SiO₂ substrate having a trench structure having an aspect ratio of 22.6:1 (length:diameter).

The right diagram of FIG. 1 corresponds to an experiment in which the inorganic precursor pulse according to the present invention was added and then the film-forming material pulse was added, and is referred to as the second process.

Specifically, a cycle of injecting the inorganic precursor pulse for 3 seconds and then performing purging for 6 seconds; injecting the film-forming material pulse for 3 seconds and then performing purging for 6 seconds; and injecting a reaction gas pulse for 3 seconds and then performing purging for 6 seconds is included. The substrate on which the metal oxide film was to be formed was heated to 320° C., and pressure in the reaction chamber was controlled at 0.74 Torr.

### Example 7

An HfO₂ thin film as a self-limiting atomic layer was formed in the same manner as in Example 6, except that the temperature for heating the substrate in Example 6 was adjusted to 300° C.

### Example 8

An HfO₂ thin film as a self-limiting atomic layer was formed in the same manner as in Example 6, except that the temperature for heating the substrate in Example 6 was adjusted to 250° C.

### Example 9

A ZrO₂ thin film as a self-limiting atomic layer was formed in the same manner as in Example 1, except that CpZr, which is a compound represented by Chemical Formula 3-5 below, was used instead of the inorganic precursor of Example 1, the film-forming material was injected at a flow rate of 0.1 g/min, and the temperature for heating the substrate was adjusted to 320° C.

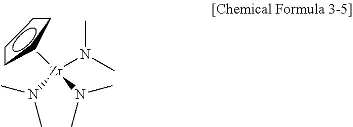

### Example 10

A Zro₂ thin film as a self-limiting atomic layer was formed in the same manner as in Example 9, except that the temperature for heating the substrate in Example 9 was adjusted to 300° C.

### Example 11

A ZrO₂ thin film as a self-limiting atomic layer was formed in the same manner as in Example 9, except that the temperature for heating the substrate in Example 9 was adjusted to 250° C.

### Example 12

A ZrO₂ thin film as a self-limiting atomic layer was formed in the same manner as in Example 1, except that CpZr, which is a compound represented by Chemical Formula 3-5 below, was used instead of the inorganic precursor of Example 6, the film-forming material was injected at a flow rate of 0.1 g/min, and the temperature for heating the substrate was adjusted to 320° C.

### Example 13

A ZrO₂ thin film as a self-limiting atomic layer was formed in the same manner as in Example 12, except that the temperature for heating the substrate in Example 12 was adjusted to 300° C.

### Example 14

A ZrO₂ thin film as a self-limiting atomic layer was formed in the same manner as in Example 12, except that the temperature for heating the substrate in Example 12 was adjusted to 250° C.

### Comparative Example 1

An HfO₂ thin film as a self-limiting atomic layer was formed in the same manner as in Example 1, except that the film-forming material of Example 1 was not added.

### Comparative Example 2

An HfO₂ thin film as a self-limiting atomic layer was formed in the same manner as in Example 2, except that the film-forming material of Example 2 was not added.

### Comparative Example 3

An HfO₂ thin film as a self-limiting atomic layer was formed in the same manner as in Example 3, except that the film-forming material of Example 3 was not added.

### Comparative Example 4

An HfO₂ thin film as a self-limiting atomic layer was formed in the same manner as in Example 6, except that the film-forming material of Example 6 was not added.

### Comparative Example 5

An HfO₂ thin film as a self-limiting atomic layer was formed in the same manner as in Example 7, except that the film-forming material of Example 7 was not added.

### Comparative Example 6

An ZrO₂ thin film as a self-limiting atomic layer was formed in the same manner as in Example 8, except that the film-forming material of Example 8 was not added.

### Comparative Example 7

A ZrO₂ thin film as a self-limiting atomic layer was formed in the same manner as in Example 9, except that the film-forming material of Example 9 was not added.

### Comparative Example 8

A ZrO₂ thin film as a self-limiting atomic layer was formed in the same manner as in Example 10, except that the film-forming material of Example 10 was not added.

### Comparative Example 9

A ZrO₂ thin film as a self-limiting atomic layer was formed in the same manner as in Example 11, except that the film-forming material of Example 11 was not added.

### Experiment Examples

### 1) Deposition Evaluation

In the case of Examples 1 to 3, Examples 5 to 8, and Comparative Examples 1 to 4, CpHf was used as the inorganic precursor. In the case of Example 4 and Comparative Example 5, TEMAH was used as the inorganic precursor. In the case of Examples 9 to 14 and Comparative Examples 6 and 7, CpZr was used as the inorganic precursor. Overall, the deposition rate decreased when the film-forming material was added before the inorganic precursor. On the other hand, when the film-forming material was added later than the inorganic precursor, the deposition rate increased (see Table 1 and FIG. 2 below).

As shown in Examples 1 to 6 and Comparative Examples 1 to 3, in the case of low temperature, this tendency became clear.

In addition, as shown in Examples 1 to 8, Comparative Examples 1 to 3, Examples 9 to 14, and Comparative Examples 6 and 7, in the case of Zro₂ thin film, this tendency became clear.

TABLE 1

| | Film-forming | Inorganic | Deposition rate |
|---|---|---|---|
| Classification | material | precursor | (Å/cycle) |
| Example 1 | Tert-butyl iodide | CpHf | 0.564 |
| Example 2 | Tert-butyl iodide | CpHf | 0.583 |
| Example 3 | Tert-butyl iodide | CpHf | 0.628 |
| Example 6 | Tert-butyl iodide | CpHf | 0.845 |
| Example 7 | Tert-butyl iodide | CpHf | 0.849 |
| Example 8 | Tert-butyl iodide | CpHf | 0.942 |
| Example 9 | Tert-butyl iodide | CpZr | — |
| Example 10 | Tert-butyl iodide | CpZr | 0.643 |
| Example 11 | Tert-butyl iodide | CpZr | 0.705 |
| Example 12 | Tert-butyl iodide | CpZr | — |
| Example 13 | Tert-butyl iodide | CpZr | 0.870 |
| Example 14 | Tert-butyl iodide | CpZr | 0.896 |
| Comparative | X | CpHf | 0.716 |
| Example 1 | | | |
| Comparative | X | CpHf | 0.712 |
| Example 2 | | | |
| Comparative | X | CpHf | 0.685 |
| Example 3 | | | |
| Comparative | X | CpZr | 0.755 |
| Example 6 | | | |
| Comparative | X | CpZr | 0.737 |
| Example 7 | | | |

### 2) Impurities Reduction Characteristics

C reduction rate (%) was calculated by Equation 2 below.

$$C reduction rate = \frac{\begin{matrix}SIMS Cl intensity of \\ Comparative Example 1 - \\ SIMS Cl intensity of Example\end{matrix}}{SIMS Cl intensity of Example} \times 100 \qquad [ Equation 2 ]$$

As shown in FIG. 6 below, in the case of Examples 1 to 3 in which the film-forming material according to the present invention was used and an Hf thin film precursor was used as the inorganic precursor, compared to Comparative Example 1 (Ref HfO₂) in which the film-forming material was not used, C intensity, which indicates the amount of contaminants in the thin film, decreased significantly. These results indicates that the impurities reduction characteristics of Examples 1 to 3 are excellent.

More specifically, in the case of Example 1 (corresponding to FIG. 6(a)) in which CpHf was used at 320° C. as the inorganic precursor, compared to Comparative Example 1 (C (counts/s)=8,227), C intensity, which indicates the amount of contaminants in the thin film, decreased by 76%. In the case of Example 2 (corresponding to FIG. 6(b)) in which CpHf was used at 300° C. as the inorganic precursor, compared to Comparative Example 2, C intensity, which indicates the amount of contaminants in the thin film, decreased by 66%. In the case of Example 3 (corresponding to FIG. 6(c)) in which CpHf was used at 250° C. as the inorganic precursor, compared to Comparative Example 3 (C (counts/s)=13,745), C intensity, which indicates the amount of contaminants in the thin film, decreased by 40%. In addition, it was confirmed once again that the Hf thin film according to the present invention has excellent impurities reduction characteristics.

### 3) Thin Film Density

As shown in FIG. 7, in the case of Example 2 (thin film density: 9.40 g/cm³) and Example 3 (thin film density: 8.0 g/cm³), compared to Comparative Example 2 (9.0 g/cm³) and Comparative Example 3 (7.7 g/cm³), which were the controls of Example 2 and Example 3, respectively, it was confirmed that the thin film density measured based on X-ray reflectometry (XRR) analysis increased significantly.

Based on these results, it can be seen that the Hf and Zr thin films according to the present invention may improve crystallinity and electrical characteristics in integrated structures with high aspect ratio, such as DRAM capacitance.

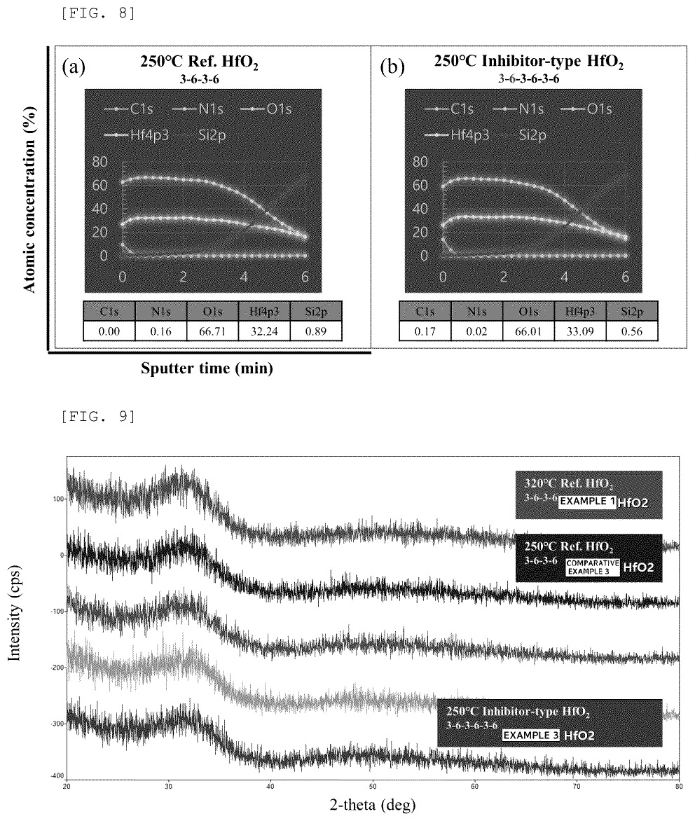

The 7 nm-thick XRD pattern deposited in the above-described Examples 1 and 3 and Comparative Example 3 is shown in FIG. 9.

As shown in FIG. 9 below, an amorphous phase indicated by a very weak diffraction pattern was observed, and no phase transition to a crystalline phase was observed at 320°. For reference, it is known that most very deposition thin films are in an amorphous state. Thus, it was confirmed that an appropriate thin film was manufactured.

### 4) Capacitance

The capacitance of the HfO₂ thin films formed in Example 1 and Comparative Example 1 was measured.

Specifically, a metal thin film was deposited on the top and bottom of a dielectric film to be measured, metals on the top and bottom were electrically connected to each other, and the capacitance was measured using CV measurement equipment at a frequency of 1 MHZ. The results are shown in Table 2 below.

### 5) Leakage Current

The leakage current of the HfO₂ thin films formed in Example 1 and Comparative Example 1 was measured at 3 MV/cm.

Specifically, the leakage current was measured in a voltage sweep mode (0-15 V) using an I-V parameter analyzer (model name: 4200-SCS; manufacturer: KEITHLEY), and the results are shown in Table 2 below.

### 6) Dielectric Constant

The dielectric constant of the HfO₂ thin films formed in Example 1 and Comparative Example 1 was measured. Specifically, the dielectric constant was measured in a DC-bias sweep mode using a C-V parameter analyzer (model name: E4980A, LCR meter: 20 Hz˜ 2 MHz, manufacturer: KEYSIGHT), and the results are shown in Table 2 below.

TABLE 2

| | | Leakage current | Dielectric |
|---|---|---|---|
| Classification | Capacitance (F) | (A/ cm²) | constant |
| Example 1 | 2.67 × 10⁻¹⁰ | 5.18 × 10⁻⁸ | 15.1 |
| Comparative | 2.54 × 10⁻¹⁰ | 1.13 × 10⁻⁶ | 14.4 |
| Example 1 | | | |

As shown in Table 2, in the case of Example 1 in which the film-forming material according to the present invention was used, compared to Comparative Example 1 in which the film-forming material according to the present invention was not used, the dielectric constant and the capacitance were improved, and the leakage current decreased significantly. Specifically, in the case of leakage current, an improvement equivalent to 95% was confirmed at 5.18×10⁻⁸ A/cm², which was lower than the DRAM leakage current limit. This greatly reduced leakage current is believed to be due to the improvement in thin film impurities and thin film density confirmed previously.

### 7) Bottom-Up Conformal Properties

The bottom-up conformal properties of the HfO₂ thin films formed in Example 1 and Comparative Example 1 were evaluated.

Specifically, according to Example 1 of the present invention or Comparative Example 1, an HfO₂ thin film was deposited at 320° C. on a substrate having a trench structure having an aspect ratio (length/diameter) of 22.6:1.

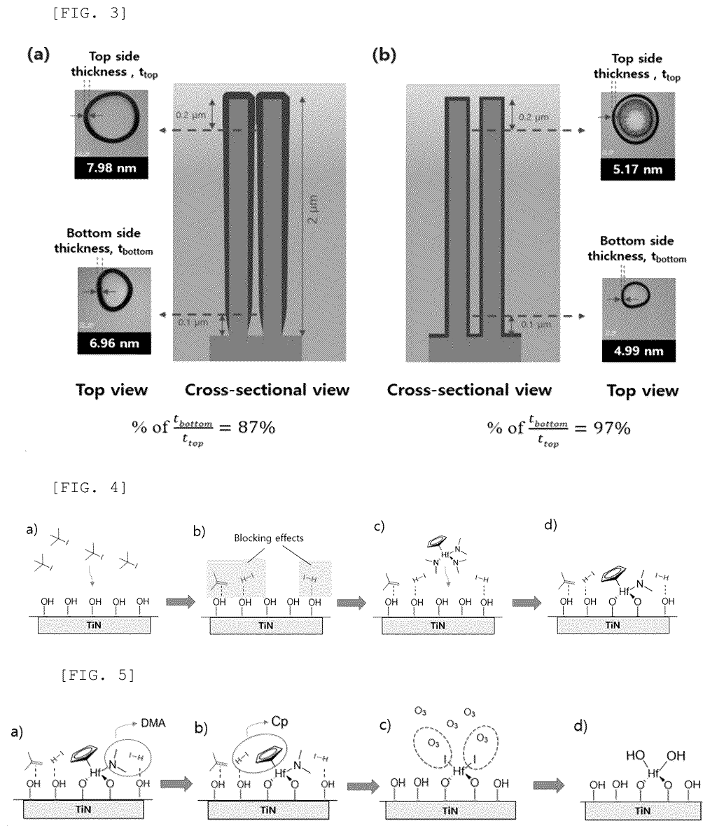

A metal thin film was deposited on the top and bottom of the HfO₂ thin film. Then, TEM images of a cross section at a point 200 nm below the top and TEM images of a cross section at a point 100 nm above the bottom were obtained, and the images are shown in FIG. 3.

As shown in FIG. 3 below, in the case of Example 1 in which the film-forming material according to the present invention was used, the thickness of the top was 5.17 nm and the thickness of the bottom was 4.99 nm, showing conformal properties of 97% (FIG. 3b). In contrast, in the case of Comparative Example 1 in which the film-forming material according to the present invention was not used, the thickness of the top was 7.98 nm and the thickness of the bottom was 6.96 nm, showing conformal properties of 87% (FIG. 3a). These results indicate that the bottom-up conformal properties of Example 1 are improved.

These results from the present invention provide compelling evidence for the promising ability of hybrid precursor pulses in ALD to achieve excellent thin film quality, high thin film conformality, and excellent electrical performance.

The present invention's innovative approach to auxiliary precursor pulses in the ALD process may provide various opportunities in application fields, such as low-resistive metal gate interconnects, high-aspect-ratio 3D metal-insulator-metal (MIM) capacitors, and DRAM trench capacitors, for future technology node and 3D device architectures such as 3D gate-all-around (GAA) and 3D NAND.

1. A film-forming material, comprising a blocking agent and a ligand exchange reaction agent.

2. The film-forming material according to claim 1, wherein the blocking agent is an unsaturated hydrocarbon having 2 to 15 carbon atoms formed from the film-forming material in a film formation process.

3. The film-forming material according to claim 1, wherein the ligand exchange reaction agent is a hydrogen halide or halogen gas that is formed from the film-forming material in the film formation process and undergoes an exchange reaction with a ligand of an inorganic precursor.

4. The film-forming material according to claim 1, wherein the film-forming material is a branched, cyclic, or aromatic compound represented by Chemical Formula 1 below. 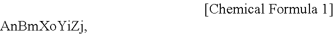
wherein A is carbon or silicon; B is hydrogen or an alkyl having 1 to 3 carbon atoms; X comprises one or more of fluorine (F), chlorine (CI), bromine (Br), and iodine (I); Y and Z independently comprise one or more selected from the group consisting of oxygen, nitrogen, sulfur, and fluorine, and are different from each other; n is an integer from 1 to 15; o is an integer greater than or equal to 1; m is 0 to 2n+1; and i and j are integers from 0 to 3.

5. A film-forming composition, comprising the film-forming material according to claim 1 and an inorganic precursor.

6. The film-forming composition according to claim 5, wherein the inorganic precursor comprises one or more selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, TI, Pb, Bi, Pt, At, and Tn.

7. The film-forming composition according to claim 5, wherein the inorganic precursor is a thin film residual precursor comprising one or more selected from the group consisting of a compound represented by Chemical Formula 2a below, a compound represented by Chemical Formula 2b below, and a compound represented by Chemical Formula 2c below. 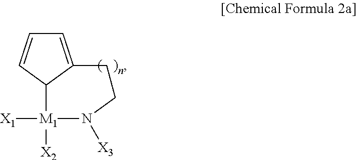
wherein M₁ is Zr, Hf, Si, Ge, or Ti; X₁, X₂, and X₃ are independently —NR₁R₂ or —OR₃; R₁ to R₃ are independently an alkyl group having 1 to 6 carbon atoms; and n is 1 or 2. 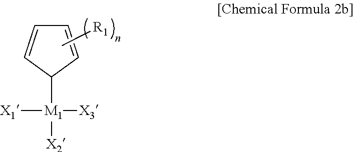
wherein M is Zr, Hf, Si, Ge, or Ti; R₁ is hydrogen or an alkyl group having 1 to 4 carbon atoms; n is an integer from 0 to 5; X′₁, X′₂, and X′₃ are independently —NR₁R₂ or —OR₃; and R′₁ to R′₃ are independently an alkyl group having 1 to 6 carbon atoms. 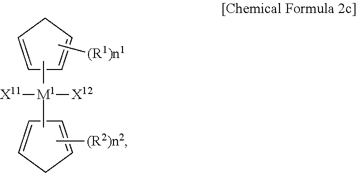
wherein M¹ is Zr, Hf, Si, Ge, or Ti; X¹¹ and X¹² are each independently selected from the group consisting of an alkyl group, —NR₃R₄, and —OR₅; R¹ to R² are each independently an alkyl group having 1 to 6 carbon atoms; and n¹ and n² are each independently an integer from 0 to 5.

8. The film-forming composition according to claim 5, wherein a weight ratio of the inorganic precursor to the film-forming material is 1:99 to 99:1.

9. The film-forming composition according to claim 5, wherein the composition comprises a pulse of a reaction gas, and the reaction gas comprises one or more selected from an oxidizing agent, a nitriding agent, and a reducing agent.

10. The film-forming composition according to claim 5, wherein the composition is a composition for bottom-up thin films or selective area thin films.

11. A film-forming method, comprising:
injecting the film-forming material of claim 1 into a chamber and depositing the film-forming material on a substrate loaded into the chamber;
injecting an inorganic precursor and depositing the inorganic precursor on the substrate; and
injecting a reaction gas pulse and depositing the reaction gas pulse on the substrate,
wherein the inorganic precursor comprises one or more selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, TI, Pb, Bi, Pt, At, and Tn.

12. A film-forming method, comprising:
injecting an inorganic precursor into a chamber and depositing the inorganic precursor on a substrate loaded into the chamber;
injecting the film-forming material of claim 1 and depositing the film-forming material on the substrate; and
injecting a reaction gas pulse and depositing the reaction gas pulse on the substrate,
wherein the inorganic precursor comprises one or more selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, TI, Pb, Bi, Pt, At, and Tn.

13. A film-forming method, comprising:
injecting the film-forming material of claim 1 and an inorganic precursor into a chamber and depositing the film-forming material and the inorganic precursor on a substrate loaded into the chamber; and
injecting a reaction gas pulse and depositing the reaction gas pulse on the substrate,
wherein the inorganic precursor comprises one or more selected from the group consisting of Li, Be, C, P, Na, Mg, Al, Si, K, Ca, Sc, Ti, V, Cr, Mn, Fe, Co, Ni, Cu, Zn, Ga, Ge, As, Se, Rb, Sr, Y, Zr, Nb, Mo, Te, Ru, Rh, Pd, Ag, Cd, In, Sn, Sb, Te, Ce, Nd, Sm, Eu, Gd, Tb, Dy, Ho, Er, Tm, Yb, Th, Pa, U, Cs, Ba, La, Hf, Ta, W, Re, Os, Ir, Pt, Au, Hg, TI, Pb, Bi, Pt, At, and Tn.

14. The film-forming method according to claim 11, wherein the substrate has an aspect ratio of 10:1 or more.

15. The film-forming method according to claim 11, wherein the film-forming method is performed at 200 to 500° C.

16. The film-forming method according to claim 11, comprising:
depositing a blocking agent and a ligand exchange reaction agent formed from the film-forming material on the substrate; and
exchanging a ligand of the inorganic precursor by the ligand exchange reaction agent.

17. The film-forming method according to claim 11, wherein the film-forming method is performed by atomic layer deposition, chemical vapor deposition, plasma atomic layer deposition, or plasma chemical vapor deposition.

18. The film-forming method according to claim 11, wherein, in the film-forming method, a thin film, in which a metal oxide thin film, a metal nitride thin film, a metal thin film, a non-metal oxide thin film, a non-metal nitride thin film, or two or more thin films thereof have a selective region, is formed.

19. A thin film formed using the film-forming method according to claim 11.

20. The thin film according to claim 19, wherein the thin film is a diffusion barrier, an etching stop film, a charge trap, a selective region deposition film, or a bottom-up thin film.

21. A semiconductor substrate, comprising the thin film according to claim 19.

22. The semiconductor substrate according to claim 21, wherein the semiconductor substrate is low-resistive metal gate interconnects, a high-aspect-ratio 3D metal-insulator-metal (MIM) capacitor, a DRAM trench capacitor, 3D gate-all-around (GAA), or 3D NAND.

23. A semiconductor device, comprising the semiconductor substrate according to claim 21.
